(19) United States
(12) Patent Application Publication
(10) Pub. No.: US 2021/0335137 A1
(43) Pub. Date: Oct. 28, 2021

(54) Dynamic Risk Assessment of a Fleet of Aircraft

(71) Applicant: LOON LLC, Mountain View, CA (US)

(72) Inventor: Salvatore J. Candido, Mountain View, CA (US)

(73) Assignee: LOON LLC, Mountain View, CA (US)

(21) Appl. No.: 16/860,958

(22) Filed: Apr. 28, 2020

(51) Int. Cl. G08G 5/00; G05D 1/00; G06F 30/20; G01W 1/10

(52) U.S. Cl. CPC G08G 5/0039; G01W 1/10; G06F 30/20; G05D 1/0027

(57) ABSTRACT

The technology relates to dynamic risk assessment of a fleet of aircraft. A method for dynamic risk assessment of a flight in a fleet of aircraft includes fetching state data for a flight from a distributed database configured to store state data for flights being performed by the fleet of aircraft; running simulations, by risk modules, based on the state data for the flight, each of the risk modules configured to assess a type of risk and output a risk score, the simulations resulting in risk scores for the flight; merging the risk scores for the flight by stacking the risk scores for the flight beginning with a highest risk score until a merged risk threshold is exceeded or each of the risk scores have been stacked; providing merged risk score data to an automated system configured to generate an automated message to the flight in response to the merged risk score data. Another method also may include fetching state data for a fleet of aircraft from a distributed database; assessing a type of risk for the fleet by running simulations based on the state data for the fleet of aircraft; assessing another type of risk for the fleet by running simulations based on the state data for the fleet of aircraft; generating fleet risk assessment data comprising a merged fleet risk score; and providing the fleet risk assessment data to an automated system configured to generate an automated message to flights in the fleet in response to the fleet risk assessment data.

### BACKGROUND OF INVENTION

Aviation typically uses one or more operators per aircraft, even when an unmanned flight is remotely operated, each set of operators considering the risks of each flight of each aircraft individually. As such, conventional techniques for determining flight risks are ill-equipped to understand and respond to flight risks in the context of a fleet of autonomous aircraft. Conventional flight risk determinations generally are made on an individual flight basis, often with deterministic or heuristic models. Such typical, deterministic flight risk analysis works for analyzing risk for a single, short-term flight from take-off to landing, but does not extend well to aircraft executing extended flights and missions (e.g., high altitude vehicles, balloons, airships, satellites).

Thus, there is a need for dynamic risk assessment of a fleet of aircraft, particularly aircraft performing longer-term missions or multiple longer-term missions without landing and re-launching.

### BRIEF SUMMARY

The present disclosure provides for techniques relating to dynamic risk assessment of a fleet of aircraft. A method for dynamic risk assessment of a flight in a fleet of aircraft includes fetching state data for a flight from a distributed database configured to store state data for a plurality of flights being performed by the fleet of aircraft; running a plurality of simulations, by a plurality of risk modules, based on the state data for the flight, each of the plurality of risk modules configured to assess a type of risk and output a risk score, the plurality of simulations resulting in a plurality of risk scores for the flight; merging the plurality of risk scores for the flight by stacking the plurality of risk scores for the flight beginning with a highest risk score until a merged risk threshold is exceeded or each of the plurality of risk scores have been stacked; providing merged risk score data to an automated system configured to generate an automated message to the flight in response to the merged risk score data.

In some examples, the method may further include presenting, by a user interface, a graphical representation of the merged risk score data for the flight, the graphical representation showing at least a merged risk score and the highest risk score, the merged risk score comprising an ordered stack of the plurality of risk scores. In some examples, the method also may include causing the automated system to generate the automated message to the flight, wherein one or more of the plurality of risk modules exceeds an individual risk threshold. In some examples, the method also may include causing the automated system to generate the automated message to the flight, wherein the merged risk score exceeds the merged risk threshold.

In some examples, the automated message is configured to cause an adjustment to a flight path. In some examples, the state data comprises a population density being overflown. In some examples, the state data comprises a weather forecast. In some examples, the state data comprises observed weather. In some examples, the state data comprises a time of day. In some examples, the fleet comprises two or more homogeneous vehicles. In some examples, the fleet comprises two or more heterogeneous vehicles. In some examples, the fleet includes a wind-driven vehicle. In some examples, the fleet includes an airship. In some examples, the fleet includes a fixed-wing aircraft. In some examples, the plurality of risk modules comprises at least one of a critical battery module, a thermal runaway module, a population density module, or a ACS usage module.

A distributed computing system includes a distributed database configured to store state data for a plurality of flights being performed by a fleet of aircraft; one or more processors configured to dynamically assess risk for the plurality of flights, the one or more processors configured to: fetch state data for a flight from the distributed database, implement a plurality of risk modules to run a plurality of simulations based on the state data for the flight, each of the plurality of risk modules configured to assess a type of risk and output a risk score, the plurality of simulations resulting in a plurality of risk scores for the flight, merge the plurality of risk scores for the flight by stacking the plurality of risk scores for the flight beginning with a highest risk score until a maximum merged risk score is exceeded, and provide merged risk score data to an automated system configured to generate an automated message to the flight in response to the merged risk score data.

In some examples, the system also may include a display configured to present a user interface configured to present a graphical representation of the merged risk score data for the flight, the graphical representation showing at least a merged risk score and the highest risk score, the merged risk score comprising an ordered stack of the plurality of risk scores.

A method for dynamic risk assessment of a fleet of aircraft includes fetching state data for a fleet of aircraft from a distributed database; assessing a first type of risk for the fleet by running a first plurality of simulations, by a first risk module, based on the state data for the fleet of aircraft, the first plurality of simulations resulting in a first plurality of risk scores for the first type of risk for a plurality of flights in the fleet; assessing a second type of risk for the fleet by running a second plurality of simulations, by a second risk module, based on the state data for the fleet of aircraft, the second plurality of simulations resulting in a second plurality of risk scores for the second type of risk for the plurality of flights in the fleet; generating fleet risk assessment data comprising a merged fleet risk score comprising the first plurality of risk scores representing the first type of risk and the second plurality of risk scores representing the second type of risk; and providing the fleet risk assessment data to an automated system configured to generate an automated message to one or more flights in the fleet in response to the fleet risk assessment data.

In some examples, the method further may include aggregating the first plurality of risk scores to generate a first aggregate risk score; and aggregating the second plurality of risk scores to generate a second aggregate risk score, wherein the merged fleet risk score merges the first aggregate risk score with the second aggregate risk score. In some examples, the first type of risk is population overflown, the first aggregate risk score indicating whether a threshold cumulative population overflown by the fleet has been met or exceeded.

### BRIEF DESCRIPTION OF THE DRAWINGS

FIGS. 1A-1B are diagrams of exemplary operational systems for which a dynamic risk assessment may be computed, in accordance with one or more embodiments;

FIG. 2 is a diagram of an exemplary aerial vehicle network, in accordance with one or more embodiments;

FIG. 3A is a simplified block diagram of an exemplary computing system forming part of the systems of FIGS. 1A-2, in accordance with one or more embodiments;

FIG. 3B is a simplified block diagram of an exemplary distributed computing system, in accordance with one or more embodiments;

FIG. 4 is a simplified block diagram of an exemplary distributed architecture of a dynamic risk assessment system, in accordance with one or more embodiments;

FIGS. 5A-5D are exemplary visualizations of individual and merged risk assessments, in accordance with one or more embodiments;

FIG. 6 is a flow diagram illustrating a method for dynamic risk assessment of a fleet of aircraft, in accordance with one or more embodiments;

FIG. 7 is a flow diagram illustrating an alternative method for dynamic risk assessment of a fleet of aircraft, in accordance with one or more embodiments.

The figures depict various example embodiments of the present disclosure for purposes of illustration only. One of ordinary skill in the art will readily recognize from the following discussion that other example embodiments based on alternative structures and methods may be implemented without departing from the principles of this disclosure, and which are encompassed within the scope of this disclosure.

### DETAILED DESCRIPTION

The Figures and the following description describe certain embodiments by way of illustration only. One of ordinary skill in the art will readily recognize from the following description that alternative embodiments of the structures and methods illustrated herein may be employed without departing from the principles described herein. Reference will now be made in detail to several embodiments, examples of which are illustrated in the accompanying figures.

The above and other needs are met by the disclosed methods, a non-transitory computer-readable storage medium storing executable code, and systems for dispatching fleets of aircraft by a fleet management and flight planning system. The terms “aerial vehicle” and “aircraft” are used interchangeably herein to refer to any type of vehicle capable of aerial movement, including, without limitation, High Altitude Platforms (HAPs), High Altitude Long Endurance (HALE) aircraft, unmanned aerial vehicles (UAVs), passive lighter than air vehicles (e.g., floating stratospheric balloons, other floating or wind-driven vehicles), powered lighter than air vehicles (e.g., balloons and airships with some propulsion capabilities), fixed-wing vehicles (e.g., drones, rigid kites, gliders), various types of satellites, and other high altitude aerial vehicles.

The invention is directed to a dynamic risk assessment and adjustment system for a fleet of aircraft. The system is implemented as a distributed computing system, with the state of the aircraft fleet stored in, and shared by, a distributed database (e.g., Spanner). The system also comprises a plurality of worker pools, each configured to fetch data from the distributed database and to run expensive calculations, such as Monte Carlo simulations, to output a set of risk probabilities. Each type of risk (e.g., critical battery failure or other low energy threshold, failure to maintain sufficient separation between vehicles (i.e., a vehicle falling within a vehicle proximity threshold), a vehicle using a buoyant gas under superpressure hitting a zero pressure threshold, a wind-driven vehicle's lift gas dropping below a threshold, or lift gas-ballast-temperature balance exceeding a balance threshold, system experiencing a critical drop in temperature, vehicle flying or drifting over population density beyond the scope of its safety case, altitude control system usage threshold) is assessed by a simulation module (e.g., critical battery module, thermal runaway module, population density module, ACS usage module, etc.). For redundancy and resiliency of the fleet management system, the distributed database and each of the worker pools may be run out of different datacenters.

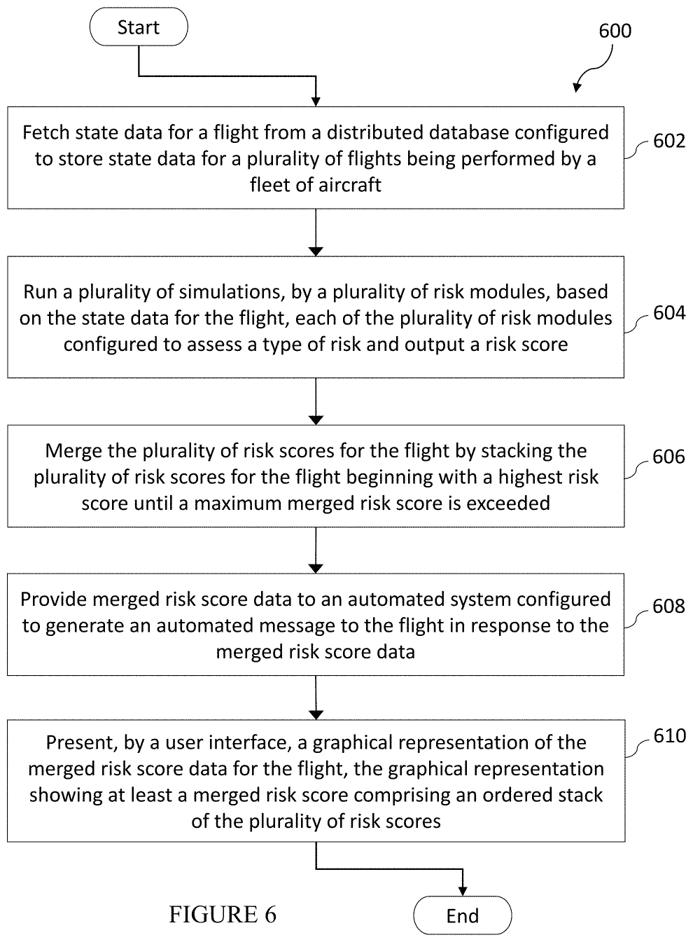

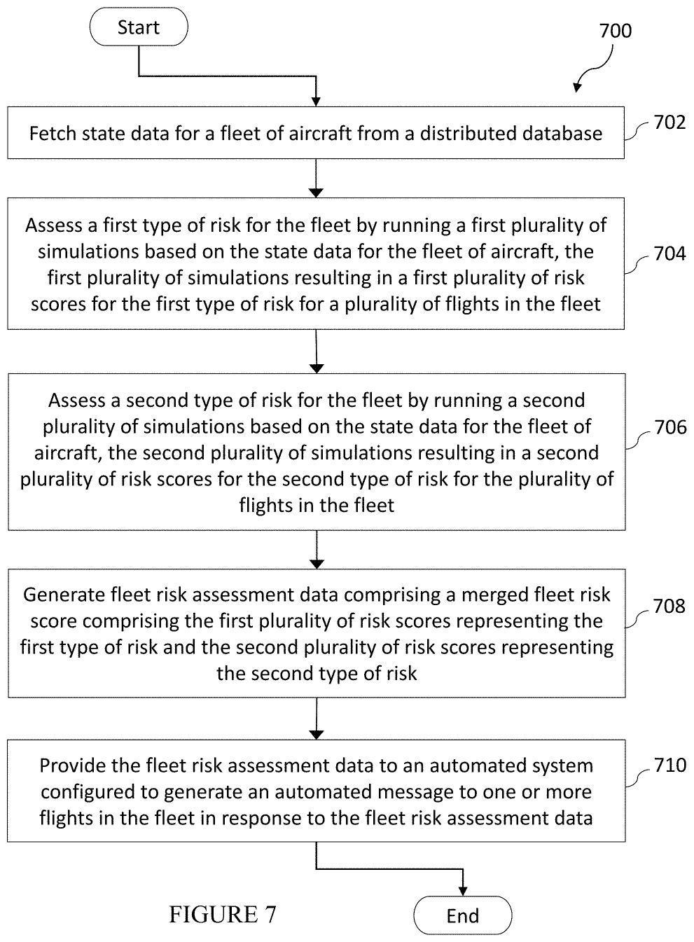

A worker pool may be configured to perform two types of work. First, a worker pool may run a module to assess a type of risk and to output a risk probability for said type of risk for a fleet or other grouping of flights. In some examples, a worker pool may be configured to run simulations (e.g., Monte Carlos), or other expensive calculations to generate risk probability outputs. In some examples, the risk probability outputs may be aggregated and/or broken down into risk probabilities for individual flights. Second, a worker may merge risk assessments from multiple modules for a given flight. Example methods for merging risk assessments from multiple modules are described herein (e.g., in FIGS. 6-7). In other examples, a worker also may be configured to use external APIs to effect changes in other worker jobs (e.g., based on additional computations or computations from other workers). For example, a worker may use output from a battery module to adjust power safety thresholds in other modules over a time period.

The output of the worker pool comprises risk probability data (“risk score data”) from a risk simulation module, which may then be merged into a merged risk assessment for that flight, the merged risk assessment for the given flight being output by the worker pool. The risk score data being output by each simulation module may comprise a risk score within a predetermined range expressed as a value range (e.g., 0.1 to 1, 1 to 10, or other range) or as a likelihood per flight hour range (e.g., number of unplanned terminations per flight hour, per flight day, per flight week, or more), wherein all of the simulation modules are calibrated to output a risk score within the predetermined range. In some examples, the output of the plurality of worker pools may be aggregated to generate aggregate risk assessment data for the fleet.

In other examples, a set of worker pools may update risk for an entire fleet at the same time, with each worker pool directed to a type of risk and multiple workers within that pool assessing that type of risk for all the flights in the fleet. The output of each worker pool may be aggregated to generate an aggregate risk assessment for the fleet. The output of each worker pool also may be broken out into a risk assessment for each flight for that simulation module, which also may be merged to generate merged risk assessments for each flight. In an example, where each worker pool is directed to run simulations assessing one type of risk for a fleet, a first worker pool may assess a risk of a thermal runaway, a second worker pool may assess a risk of critical battery levels (i.e., running out of power or power over-use), a third worker pool may assess operational risk based on population density flown over by a likely path, a fourth worker pool may assess ACS lifecycle risk based on ACS usage, a fifth worker pool may assess risk of reaching zero pressure, and so on. In this example, a set of worker pools may assess a slate of risks for a fleet at the same or overlapping times to provide an overall fleet risk assessment.

As these modules are performing calculations (e.g., that are non-instantaneous), tasks for individual risk assessment modules may be scheduled and coordinated such for efficiency of data flow between the individual risk modules and a risk merging module.

Merging the risk assessments from the simulation modules may be accomplished by stacking the risks according to the output risk score. For example, the risk scores are merged (i.e., stacked) starting with the largest risks (i.e., highest risk score or unplanned termination rate (“UTR”)), and adding a next largest risk, and on until all risk modules have been added. In an example:

merged UTR=UTR from zero pressure+UTR from running out of battery+k

where k is a baseline not calculated risk, such as risk of random hardware failure or other reliability baseline not calculated online for the flight vehicle.
A merged UTR may further be used to calculate risk of fatality or injury:

Injury Rate=UTR*f(population density below vehicle)

where f is a model of how likely a descent into this population density is to cause an injury.

In another example, a merged risk score may include calculating actual quantities in a risk case: risk of injury/flight hour=risk UT/hr*population density overflown*likelihood of injury given landing. In this case, risk of unplanned termination (“UT”)/hr and population density overflown may be calculated dynamically, and likelihood of injury given landing may be a constant derived through analysis of the flight system. Such risk analysis may be aggregated across the fleet to derive an aggregate risk of injury per flight hour and expected number of injuries per time period (e.g., year or a number of flight hours, etc.). An aggregate risk of injury per flight hour may comprise a fleet-wide aggregation, and also may be aggregated for desired geolocales (e.g., states, countries, continents, hemispheres, climate regions, and other regions). In yet another example, a unitless calculation may be used to derive merged risk data, e.g., stacking risks without summing.

Merged risk score data may be sent to flight engineers and/or automated systems based on either (a) an individual risk score exceeding an individual risk module threshold, or (b) a maximum merged risk threshold is met or exceeded. Said flight engineers and automated systems may act on the merged risk score data, for example, to send commands or other messages to the flight or the fleet.

For example, a population density or balloon proximity risk score that exceeds a threshold for a flight (i.e., an expected path of the flight will fly over an area that exceeds threshold population density, or too close to another flight, increasing overall operational risk) may be provided to a flight planning system to tune the flight plan (e.g., to increase favoring avoidance of densely populated areas (e.g., cities) over speed or to increase avoidance of other objects). In another example, a merged risk assessment for a flight may be output to a flight engineer to alert the flight engineer to a risk level (i.e., time frame) for a zero pressure module, or critical battery module, or ACS usage module, that may require monitoring or flight termination (e.g., bringing the flight down in the next 72 hours, or week, or other similar time frame).

The output of these risk assessment modules may be used to update a periodic (e.g., quarterly or annual) safety case, indicating aggregate fleet risk or merged risk for any individual vehicle. In an example, a cumulative population overflown by the fleet (e.g., over a period of days or other period of time) may be analyzed and compared against a threshold cumulative population overflown by fleet, and used to adjust flight paths of certain flights (e.g., flights performing low priority tasks or time flexible tasks may, flights with alternative paths that result in very little change to probabilities of meeting objectives (e.g., time, location, level of service) and steep decreases in population overflown) to reduce overall fleet risk exposure. In another example, an individual flight's population overflown risk may be analyzed and compared against a threshold population density overflown (e.g., no greater than X number of people per km2) and may have its individual flight path adjusted (e.g., maneuver around the outskirts of a city, or otherwise avoid flying over dense populations, to get to a destination) to reduce the population density overflown by the individual flight. In other examples, merged risk assessments for various flights also may be grouped, classified, and otherwise aggregate for a region, a vehicle type or class, or the overall fleet.

### Example Systems

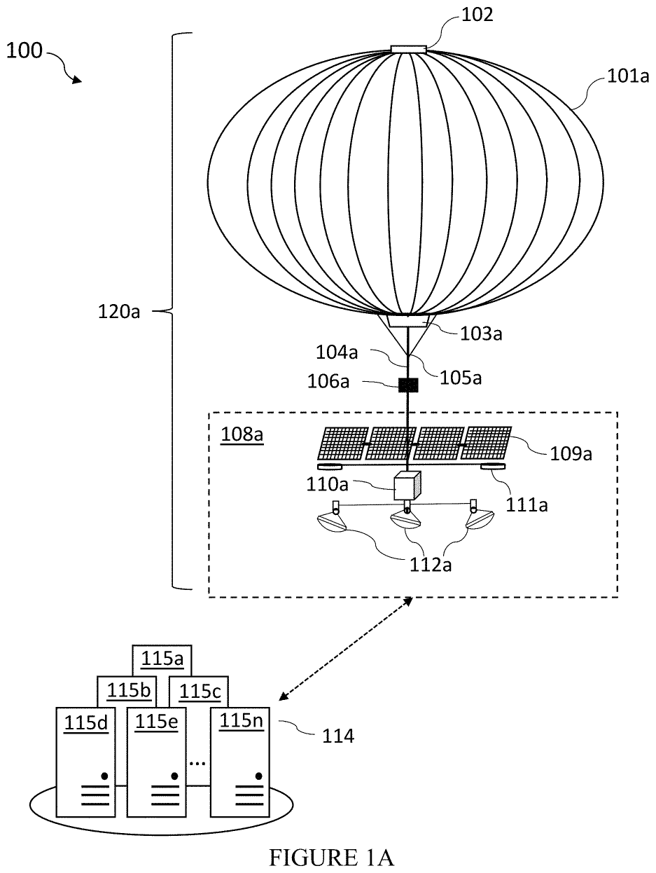

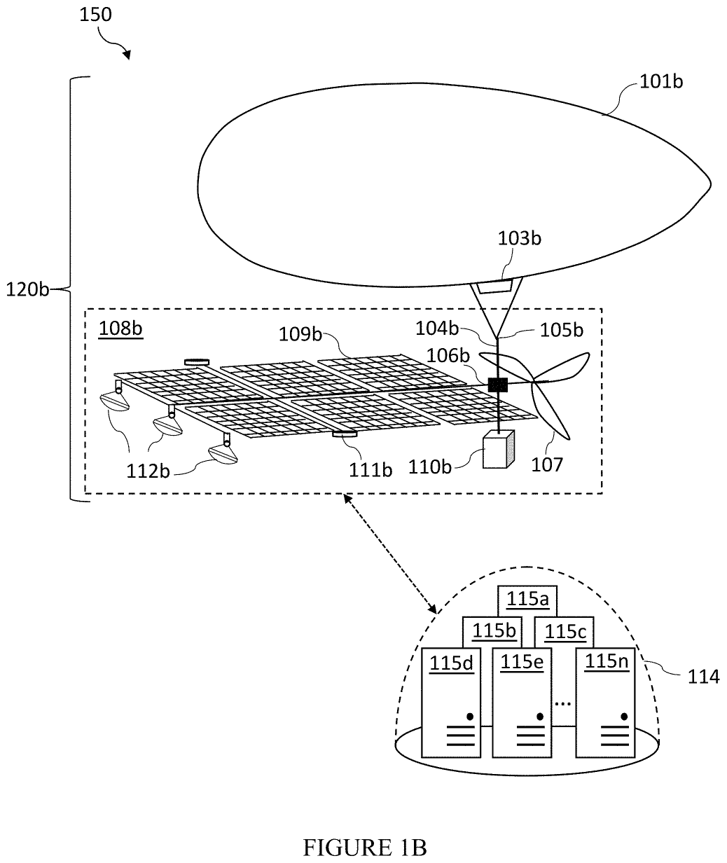

FIGS. 1A-1B are diagrams of exemplary operational systems in which flight policies may be implemented for navigating an aerial vehicle, in accordance with one or more embodiments. In FIG. 1A, there is shown a diagram of system 100 for navigation of aerial vehicle 120a. In some examples, aerial vehicle 120a may be a passive vehicle, such as a balloon or satellite, wherein most of its directional movement is a result of environmental forces, such as wind and gravity. In other examples, aerial vehicles 120a may be actively propelled. In an embodiment, system 100 may include aerial vehicle 120a and ground station 114. In this embodiment, aerial vehicle 120a may include balloon 101a, plate 102, altitude control system (ACS) 103a, connection 104a, joint 105a, actuation module 106a, and payload 108a. In some examples, plate 102 may provide structural and electrical connections and infrastructure. Plate 102 may be positioned at the apex of balloon 101a and may serve to couple together various parts of balloon 101a. In other examples, plate 102 also may include a flight termination unit, such as one or more blades and an actuator to selectively cut a portion and/or a layer of balloon 101a. ACS 103a may include structural and electrical connections and infrastructure, including components (e.g., fans, valves, actuators, etc.) used to, for example, add and remove air from balloon 101a (i.e., in some examples, balloon 101a may include an interior ballonet within its outer, more rigid shell that is inflated and deflated), causing balloon 101a to ascend or descend, for example, to catch stratospheric winds to move in a desired direction. Balloon 101a may comprise a balloon envelope comprised of lightweight and/or flexible latex or rubber materials (e.g., polyethylene, polyethylene terephthalate, chloroprene), tendons (e.g., attached at one end to plate 102 and at another end to ACS 103a) to provide strength to the balloon structure, a ballonet, along with other structural components. In various embodiments, balloon 101a may be non-rigid, semi-rigid, or rigid.

Connection 104a may structurally, electrically, and communicatively, connect balloon 101a and/or ACS 103a to various components comprising payload 108a. In some examples, connection 104a may provide two-way communication and electrical connections, and even two-way power connections. Connection 104a may include a joint 105a, configured to allow the portion above joint 105a to pivot about one or more axes (e.g., allowing either balloon 101a or payload 108a to tilt and turn). Actuation module 106a may provide a means to actively turn payload 108a for various purposes, such as improved aerodynamics, facing or tilting solar panel(s) 109a advantageously, directing payload 108a and propulsion units (e.g., propellers 107 in FIG. 1B) for propelled flight, or directing components of payload 108a advantageously.

Payload 108a may include solar panel(s) 109a, avionics chassis 110a, broadband communications unit(s) 111a, and terminal(s) 112a. Solar panel(s) 109a may be configured to capture solar energy to be provided to a battery or other energy storage unit, for example, housed within avionics chassis 110a. Avionics chassis 110a also may house a flight computer (e.g., computing device 301, as described herein), a transponder, along with other control and communications infrastructure (e.g., a controller comprising another computing device and/or logic circuit configured to control aerial vehicle 120a). Communications unit(s) 111a may include hardware to provide wireless network access (e.g., LTE, fixed wireless broadband via 5G, Internet of Things (IoT) network, free space optical network or other broadband networks). Terminal(s) 112a may comprise one or more parabolic reflectors (e.g., dishes) coupled to an antenna and a gimbal or pivot mechanism (e.g., including an actuator comprising a motor). Terminal(s) 112(a) may be configured to receive or transmit radio waves to beam data long distances (e.g., using the millimeter wave spectrum or higher frequency radio signals). In some examples, terminal(s) 112a may have very high bandwidth capabilities. Terminal(s) 112a also may be configured to have a large range of pivot motion for precise pointing performance. Terminal(s) 112a also may be made of lightweight materials.

In other examples, payload 108a may include fewer or more components, including propellers 107 as shown in FIG. 1B, which may be configured to propel aerial vehicles 120a-b in a given direction. In still other examples, payload 108a may include still other components well known in the art to be beneficial to flight capabilities of an aerial vehicle. For example, payload 108a also may include energy capturing units apart from solar panel(s) 109a (e.g., rotors or other blades (not shown) configured to be spun by wind to generate energy). In another example, payload 108a may further include or be coupled to an imaging device, such as a downward-facing camera and/or a star tracker. In yet another example, payload 108a also may include various sensors (not shown), for example, housed within avionics chassis 110a or otherwise coupled to connection 104a or balloon 101a. Such sensors may include Global Positioning System (GPS) sensors, wind speed and direction sensors such as wind vanes and anemometers, temperature sensors such as thermometers and resistance temperature detectors, speed of sound sensors, acoustic sensors, pressure sensors such as barometers and differential pressure sensors, accelerometers, gyroscopes, combination sensor devices such as inertial measurement units (IMUs), light detectors, light detection and ranging (LIDAR) units, radar units, cameras, other image sensors, and more. These examples of sensors are not intended to be limiting, and those skilled in the art will appreciate that other sensors or combinations of sensors in addition to these described may be included without departing from the scope of the present disclosure.

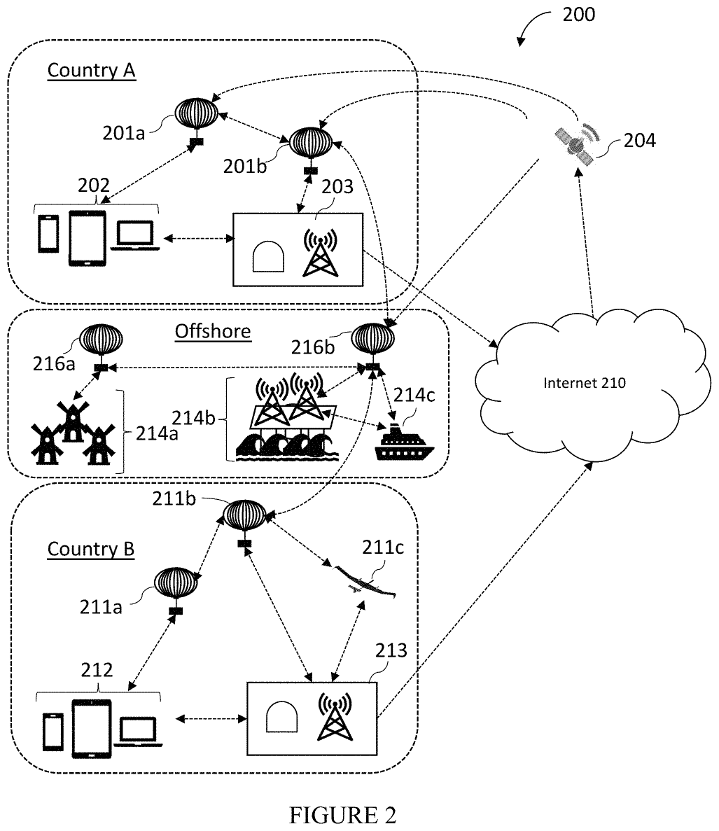

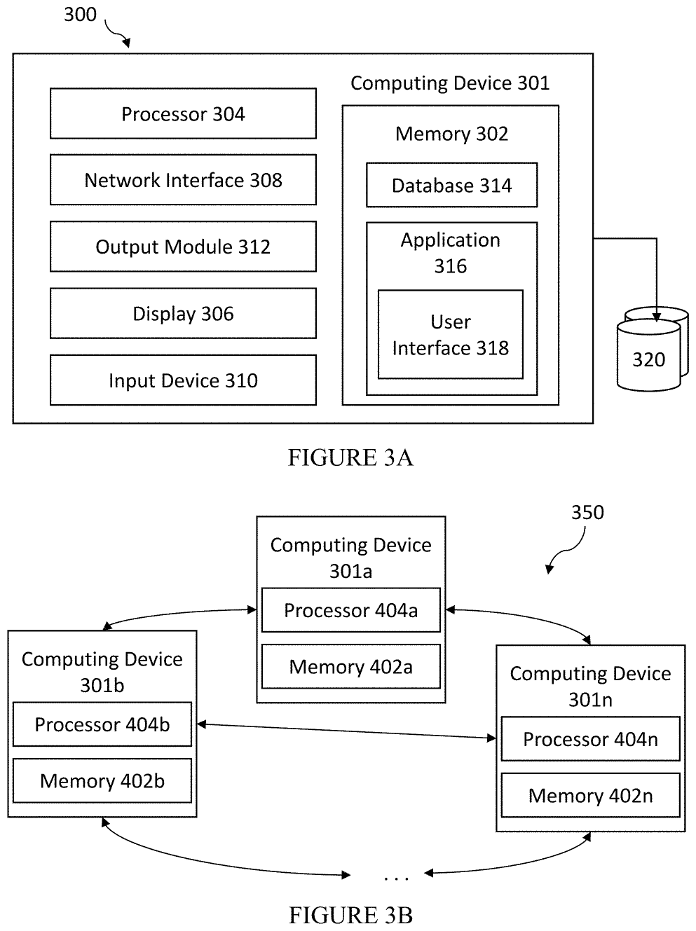

Ground station 114 may include one or more server computing devices 115a-n, which in turn may comprise one or more computing devices (e.g., computing device 301 in FIG. 3). In some examples, ground station 114 also may include one or more storage systems, either housed within server computing devices 115a-n, or separately (see, e.g., computing device 301 and repositories 320). Ground station 114 may be a datacenter servicing various nodes of one or more networks (e.g., aerial vehicle network 200 in FIG. 2).

FIG. 1B shows a diagram of system 150 for navigation of aerial vehicle 120b. All like-numbered elements in FIG. 1B are the same or similar to their corresponding elements in FIG. 1A, as described above (e.g., balloon 101a and balloon 101b may serve the same function, and may operate the same as, or similar to, each other). In some examples, balloon 101b may comprise an airship hull or dirigible balloon. In this embodiment, aerial vehicle 120b further includes, as part of payload 108b, propellers 107, which may be configured to actively propel aerial vehicle 120b in a desired direction, either with or against a wind force to speed up, slow down, or re-direct, aerial vehicle 120b. In this embodiment, balloon 101b also may be shaped differently from balloon 101a, to provide different aerodynamic properties.

As shown in FIGS. 1A-1B, aerial vehicles 120a-b may be largely wind-influenced aerial vehicle, for example, balloons carrying a payload (with or without propulsion capabilities) as shown, or fixed wing high altitude drones (e.g., aerial vehicle 211c in FIG. 2) with gliding and/or full propulsion capabilities. However, those skilled in the art will recognize that the systems and methods disclosed herein may similarly apply and be usable by various other types of aerial vehicles.

FIG. 2 is a diagram of an exemplary aerial vehicle network, in accordance with one or more embodiments. Aerial vehicle network 200 may include aerial vehicles 201a-b, user devices 202, and ground infrastructure 203, in Country A. Aerial vehicle network 200 also may include aerial vehicles 211a-c, user devices 212, and ground infrastructure 213 in Country B. Aerial vehicle network 200 also may include offshore facilities 214a-c and aerial vehicles 216a-b servicing at least said offshore facilities 214a-c. Aerial network 200 may further include satellite 204 and Internet 210. Aerial vehicles 201a-b, 211a-c, and 216a-b may comprise balloon, other floating (i.e., lighter than air), propelled or partially propelled (i.e., propelled for a limited amount of time or under certain circumstances, and not propelled at other times or under other circumstances), fixed-wing, or other types of high altitude aerial vehicles, as described herein. For example, aerial vehicles 201a-b, 211a-c, and 216a-b may be the same or similar to aerial vehicles 120a-b described above. User devices 202 and 212 may include a cellular phone, tablet computer, smart phone, desktop computer, laptop computer, and/or any other computing device known to those skilled in the art. Ground infrastructure 203 and 213 may include always-on or fixed location computing device (i.e., capable of receiving fixed broadband transmissions), ground terminal (e.g., ground station 114), tower (e.g., a cellular tower), and/or any other fixed or portable ground infrastructure for receiving and transmitting various modes of connectivity described herein known to those skilled in the art. User devices 202 and 212, ground infrastructure 203 and 213, and offshore facilities 214a-c, may be capable of receiving and transmitting signals to and from aerial vehicles 201a-b, 211a-c, and 216a-b, and in some cases, to and from each other. Offshore facilities 214a-c may include industrial facilities (e.g., wind farms, oil rigs and wells), commercial transport (e.g., container ships, other cargo ships, tankers, other merchant ships, ferries, cruise ships, other passenger ships), and other offshore applications.

Aerial vehicle network 200 may support ground-to-vehicle communication and connectivity, as shown between ground infrastructure 203 and aerial vehicle 201b, as well as aerial vehicles 211b-c and ground infrastructure 213. In these examples, aerial vehicles 201b and 211b-c each may exchange data with either or both a ground station (e.g., ground station 114), a tower, or other ground structures configured to connect with a grid, Internet, broadband, and the like. Aerial vehicle network 200 also may support vehicle-to-vehicle (e.g., between aerial vehicles 201a and 201b, between aerial vehicles 211a-c, between aerial vehicles 216a-b, between aerial vehicles 201b and 216b, between aerial vehicles 211b and 216b), satellite-to-vehicle (e.g., between satellite 204 and aerial vehicles 201a-b, between satellite 204 and aerial vehicle 216b), vehicle-to-user device (e.g., between aerial vehicle 201a and user devices 202, between aerial vehicle 211a and user devices 212), and vehicle-to-offshore facility (e.g., between one or both of aerial vehicles 216a-b and one or more of offshore facilities 214a-c) communication and connectivity. In some examples, ground stations within ground infrastructures 203 and 213 may provide core network functions, such as connecting to the Internet and core cellular data network (e.g., connecting to LTE EPC or other communications platforms, and a software defined network system) and performing mission control functions. In some examples, the ground-to-vehicle, vehicle-to-vehicle, and satellite-to-vehicle communication and connectivity enables distribution of connectivity with minimal ground infrastructure. For example, aerial vehicles 201a-b, 211a-c, and 216a-b may serve as base stations (e.g., LTE eNodeB base stations), capable of both connecting to the core network (e.g., Internet and core cellular data network), as well as delivering connectivity to each other, to user devices 202 and 212, and to offshore facilities 214a-c. As such, aerial vehicles 201a-b and 211a-c represent a distribution layer of aerial vehicle network 200. User devices 202 and 212 each may access cellular data and Internet connections directly from aerial vehicles 201a-b and 211a-c. In some examples, one or more of aerial vehicles 201a-b, 211a-c, and 216a-b may be part of a single fleet of homogeneous or heterogeneous aircraft, the merged risk for each or all being determined by methods described herein.

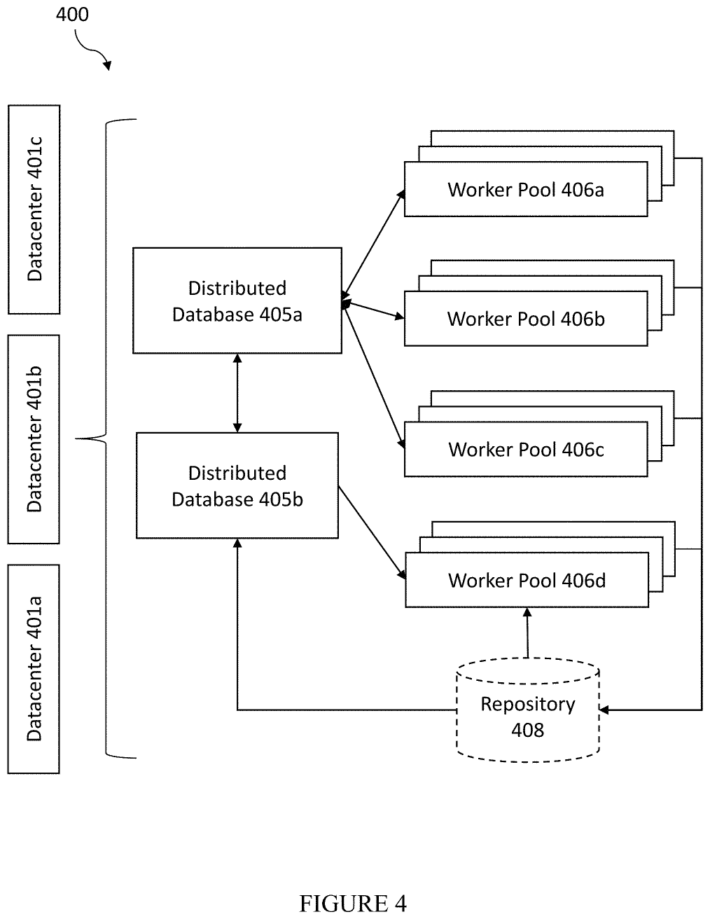

FIG. 3A is a simplified block diagram of an exemplary computing system forming part of the systems of FIGS. 1A-2, in accordance with one or more embodiments. In one embodiment, computing system 300 may include computing device 301 and storage system 320. Storage system 320 may comprise a plurality of repositories and/or other forms of data storage, and it also may be in communication with computing device 301. In another embodiment, storage system 320, which may comprise a plurality of repositories, may be housed in one or more of computing device 301 (not shown). In some examples, storage system 320 may store state data, commands, flight policies, and other various types of information as described herein. This information may be retrieved or otherwise accessed by one or more computing devices, such as computing device 301 or server computing devices 410 in FIG. 4, in order to perform some or all of the features described herein. Storage system 320 may comprise any type of computer storage, such as a hard-drive, memory card, ROM, RAM, DVD, CD-ROM, write-capable, and read-only memories. In addition, storage system 320 may include a distributed storage system where data is stored on a plurality of different storage devices, which may be physically located at the same or different geographic locations (e.g., in a distributed computing system such as system 400 in FIG. 3B). Storage system 320 may be networked to computing device 301 directly using wired connections and/or wireless connections. Such network may include various configurations and protocols, including short range communication protocols such as Bluetooth™, Bluetooth™ LE, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

Computing device 301 also may include a memory 302. Memory 302 may comprise a storage system configured to store a database 314 and an application 316. Application 316 may include instructions which, when executed by a processor 304, cause computing device 301 to perform various steps and/or functions, as described herein. Application 316 further includes instructions for generating a user interface 318 (e.g., graphical user interface (GUI)). Database 314 may store various algorithms and/or data, including neural networks (e.g., encoding flight policies, as described herein) and data regarding wind patterns, weather forecasts, past and present locations of aerial vehicles (e.g., aerial vehicles 120a-b, 201a-b, 211a-c), sensor data, map information, air traffic information, among other types of data. Memory 302 may include any non-transitory computer-readable storage medium for storing data and/or software that is executable by processor 304, and/or any other medium which may be used to store information that may be accessed by processor 304 to control the operation of computing device 301.

Computing device 301 may further include a display 306, a network interface 308, an input device 310, and/or an output module 312. Display 306 may be any display device by means of which computing device 301 may output and/or display data. Network interface 308 may be configured to connect to a network using any of the wired and wireless short range communication protocols described above, as well as a cellular data network, a satellite network, free space optical network and/or the Internet. Input device 310 may be a mouse, keyboard, touch screen, voice interface, and/or any or other hand-held controller or device or interface by means of which a user may interact with computing device 301. Output module 312 may be a bus, port, and/or other interface by means of which computing device 301 may connect to and/or output data to other devices and/or peripherals.

In some examples computing device 301 may be located remote from an aerial vehicle (e.g., aerial vehicles 120a-b, 201a-b, 211a-c) and may communicate with and/or control the operations of an aerial vehicle, or its control infrastructure as may be housed in avionics chassis 110a-b, via a network. In one embodiment, computing device 301 is a datacenter or other control facility (e.g., configured to run a distributed computing system as described herein), and may communicate with a controller and/or flight computer housed in avionics chassis 110a-b via a network. As described herein, system 300, and particularly computing device 301, may be used for planning a flight path or course for an aerial vehicle based on wind and weather forecasts to move said aerial vehicle along a desired heading or within a desired radius of a target location. Various configurations of system 300 are envisioned, and various steps and/or functions of the processes described below may be shared among the various devices of system 300 or may be assigned to specific devices.

FIG. 3B is a simplified block diagram of an exemplary distributed computing system, in accordance with one or more embodiments. System 350 may comprise two or more computing devices 301a-n. In some examples, each of 301a-n may comprise one or more of processors 404a-n, respectively, and one or more of memory 402a-n, respectively. Processors 404a-n may function similarly to processor 304 in FIG. 3, as described above. Memory 402a-n may function similarly to memory 302 in FIG. 3, as described above. In some examples, one or more of computing devices 301a-n may be a datacenter configured to perform steps in the risk assessment methods described herein.

FIG. 4 is a simplified block diagram of an exemplary distributed architecture of a dynamic risk assessment system, in accordance with one or more embodiments. Diagram 400 shows datacenters 401a-c, distributed databases 405a-b, worker pools 406a-d. In some examples, each of datacenters 401a-c may comprise the same or similar components to one of computing devices 301 and 301a-n. In some examples, distributed databases 405a-b and worker pools 406a-d may be implemented across multiple datacenters 401a-c to improve resiliency of the dynamic risk assessment system and the overall fleet management system. In some examples, one or more of worker pools 406a-d may be configured to perform expensive calculations (e.g., Monte Carlo or other forms of stochastic simulations) based on data (e.g., aircraft and fleet state data, weather data and forecasts, objective or mission of an aircraft and/or fleet, overriding factors (e.g., no-fly zones, storm locations and altitudes), aircraft and fleet characteristics) obtained from one or both of distributed databases 405a-b, in order to execute risk assessment modules (e.g., critical battery module, thermal runaway module, population density module, ACS usage module, etc.) for one or more type(s) of risk associated with a flight of an aircraft in the fleet (e.g., critical battery failure, a vehicle falling within a vehicle proximity threshold, a wind-driven vehicle hitting a zero pressure threshold, a wind-driven vehicle's lift gas dropping below a threshold, or lift gas-ballast-temperature balance exceeding a balance threshold, system experiencing a critical drop in temperature, vehicle flying or drifting over population density beyond the scope of its safety case, altitude control system overuse). In some examples, the risk probability outputs may be aggregated and/or broken down into risk probabilities for individual flights.

In other examples, one or more of worker pools 406a-d may be configured to merge risk assessments from multiple risk modules for a given flight. In still other examples, one or more of worker pools 406a-d may be configured to aggregate and/or merge risk data for the fleet. For example, one or more of worker pools 406a-d may aggregate risk data for some or all of the flights occurring or planned for the fleet for each risk module (e.g., using mean, median or other aggregation technique), and then merge the aggregated risk data to generate a merged, aggregate risk for the fleet. In another example, one or more of worker pools 406a-d may merge risk data for each flight, and then aggregate the merged risk data from some or all of the flights in the fleet to generate an aggregate of merged risk for groups within, or an entire, fleet. Examples of groups of aircraft in a fleet whose merged risk data may be of significance or interest in aggregate include, without limitation: aircraft of a given type, aircraft above or below an age threshold, aircraft in a given geographical region, aircraft with merged risks above a risk threshold. Example methods for merging risk assessments from multiple modules are described herein (e.g., in FIGS. 6-7).

Tasks for each risk assessment module may be scheduled and coordinated for efficiency of data flow between an individual risk module and a risk merging module (e.g., frameworks that route data and ensure correct timing of tasks, for example using a graph defining a workflow).

In some examples, repository 408 may store risk score data (e.g., output from worker pools 406a-d), including risk scores from risk modules and merged risk scores from merged risk modules. Such risk score data may be stored in various forms, including without limitation, a probability distribution, a histogram, a likelihood of a failure or to exceed a threshold per flight hour, or other value (e.g., derived from probabilities or other simulation outputs). In other examples, repository 408 also may store other data from sources other than worker pools 406a-d (e.g., state data, telemetry, commands or other messages). Such risk score data may be merged and/or output according to methods and interfaces described herein. The risk score data output from one or more of worker pools 406a-d may be calibrated such that each worker outputs risk scores that are within a predetermined range.

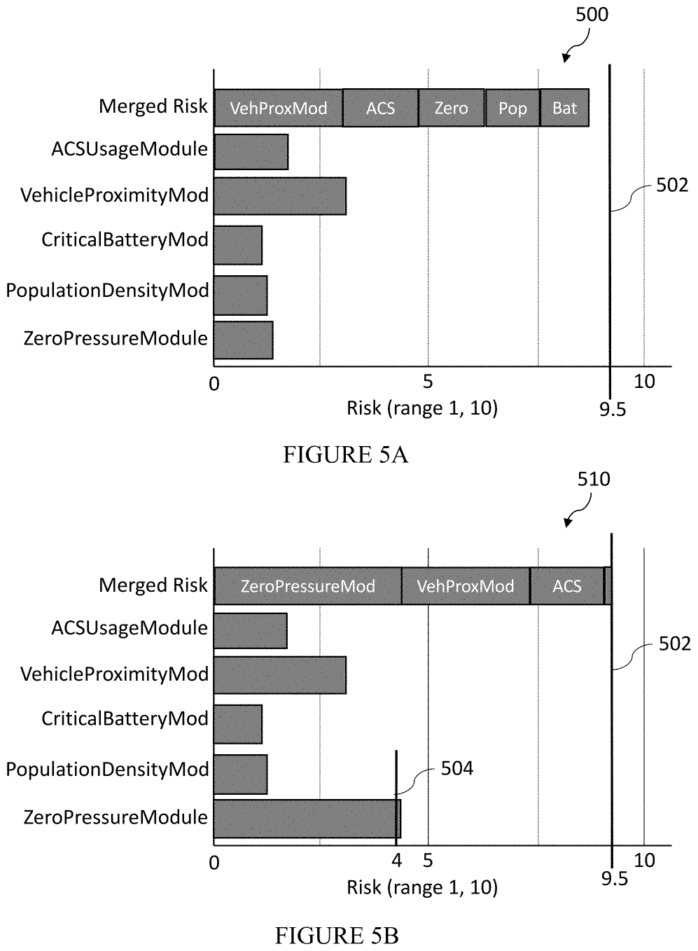

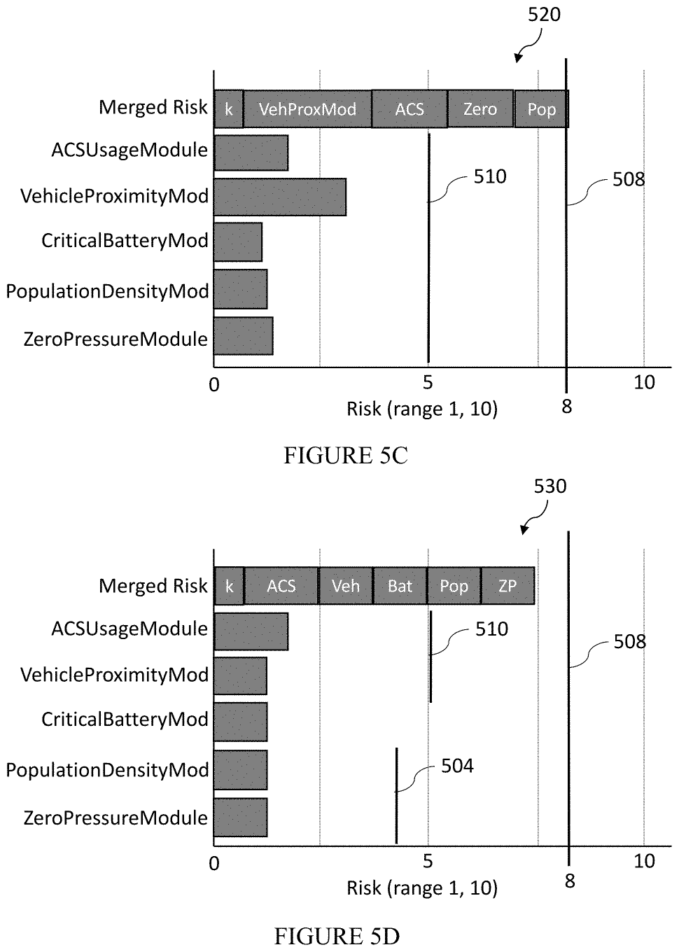

FIGS. 5A-5D are exemplary visualizations of individual and merged risk assessments, in accordance with one or more embodiments. In FIG. 5A, chart 500 shows risk scores from various risk modules, including an ACS usage module, a vehicle proximity module, a critical battery module, a population density module, and a zero pressure module. In some examples, the risk scores shown (e.g., in a range from 1-10) may comprise values that represent a risk probability determined by each module shown (e.g., based on simulations run by each module). Chart 500 also shows a merged risk, which stacks the individual risk scores from highest to lowest until it reaches a predetermined merged risk threshold 502 (e.g., score value 9.5). In chart 500, the merged risk score does not meet or exceed merged risk threshold 502. In another example, in FIG. 5B, chart 510 shows a merged risk score that exceeds merged risk threshold 502, which may cause an alarm or notification to be sent to (a) one or more interfaces accessed and viewed by a flight engineer and/or (b) an automated system configured to generate automated messages to a flight or a fleet. In some examples, individual risk thresholds also may be predetermined for each module. For example, chart 510 shows a risk score from the zero pressure module that exceeds its individual risk threshold of 4, which in itself may cause a similar alarm or notification to be similarly sent for manual or automatic handling.

Merged risk thresholds and individual risk thresholds may be different for different fleets (e.g., wind-driven, propelled, homogeneous, heterogeneous). In FIG. 5C, chart 520 shows a more conservative merged risk threshold 508 (e.g., score value 8) being exceeded by a similar set of risk scores as chart 500. Chart 520 also shows an individual risk threshold 510 for each of the individual risk modules, and a non-calculated baseline risk k. In FIG. 5D, chart 530 also shows a relatively conservative merged risk threshold 508 and a non-calculated baseline risk k, but with a merged risk score that does not exceed merged risk threshold 508. Chart 530 further shows different individual risk thresholds 504 and 510 for different risk modules.

In other examples, each of the risk scores may be shown differently (e.g., a histogram for each risk module showing a range of simulation outputs, top down views of multiple histograms (i.e., one for each risk module) stacked against each other, individual probability distributions, aggregated probability distributions).

### Example Methods

FIG. 6 is a flow diagram illustrating a method for dynamic risk assessment of a fleet of aircraft, in accordance with one or more embodiments. Method 600 begins with fetching state data for a flight from a distributed database (e.g., implemented across a plurality of datacenters) configured to store state data for a plurality of flights being performed by a fleet of aircraft at step 602. Such state data may include population density being overflown by the flight or expected to be overflown by the flight within a time frame, a weather forecast (e.g., for the flight's current location and/or planned flight path), observed weather data, a time of day, or other data relating to the flight, an aircraft performing the flight, current (e.g., observed) or future (e.g., forecasted) environmental data, or the fleet. At step 604, a plurality of simulations may be run by a plurality of risk modules (e.g., implemented in one or more worker pools across a plurality of datacenters) based on the state data for the flight, each of the plurality of risk modules configured to assess a type of risk and output a risk score. The plurality of risk scores for the flight may be merged, at step 606, by stacking the plurality of risk scores for the flight beginning with a highest risk score until a merged risk threshold (i.e., maximum allowed merged risk score) is met or exceeded. In some examples, merged risk score data may be provided to an automated system configured to generate an automated message to the flight in response to the merged risk score data at step 608. Such automated messages may include commands to the flight to cause a change in altitude (i.e., an ACS operation), heading, flight path, system mode, power mode, directionality of communication terminals (i.e., gimbal movement), and the like. In some examples, a graphical representation of the merged risk score data for the flight may be presented by a user interface at step 610, the graphical representation showing at least a merged risk score comprising an ordered stack of the plurality of risk scores. As shown in FIGS. 5A-5D, a graphical representation of some or all of the risk scores, individually or in combination, may be displayed or accessible by a user interface, even when the risk scores do not exceed any thresholds (individually or merged). When the risk scores, individually or merged, exceed a threshold, an alarm or notification also may be provided (e.g., to an automated system, a user interface, a mobile device or application, in a variety of formats, including, without limitation, visually, audibly, and haptically) in addition to presentation of the merged risk score.

FIG. 7 is a flow diagram illustrating an alternative method for dynamic risk assessment of a fleet of aircraft, in accordance with one or more embodiments. Method 700 begins with fetching state data for a fleet of aircraft from a distributed database at step 702. A first risk module may assess a first type of risk for the fleet by running a first plurality of simulations based on the state data for the fleet of aircraft at step 704. The first plurality of simulations may result in a first plurality of risk scores for the first type of risk for a plurality of flights in the fleet. A second risk module may assess a second type of risk for the fleet by running a second plurality of simulations based on the state data for the fleet of aircraft at step 708, the second plurality of simulations resulting in a second plurality of risk scores for the second type of risk for the plurality of flights in the fleet. In some examples, the tasks performed by the first risk module and the second risk module may be scheduled for efficient flow of data and use of processor resources (e.g., in parallel, in serial, overlapping in time, asynchronously). In some examples, there maybe a plurality of risk modules, each assessing a type of risk for the fleet in a similar manner. Fleet risk assessment data may be generated at step 708, said fleet risk assessment data comprising a merged fleet risk score comprising the first plurality of risk scores representing the first type of risk and the second plurality of risk scores representing the second type of risk. In some examples, the first plurality of risk scores may be aggregated into a first aggregate risk score, and the second plurality of risk scores may be aggregated into a second aggregate risk score, the first aggregate risk score and second aggregate risk score merged into the merged fleet risk score. In some examples, the fleet risk assessment data may be provided to an automated system configured to generate an automated message to one or more flights in the fleet in response to the fleet risk assessment data at step 710.

While specific examples have been provided above, it is understood that the present invention can be applied with a wide variety of inputs, thresholds, ranges, and other factors, depending on the application. For example, the time frames and ranges provided above are illustrative, but one of ordinary skill in the art would understand that these time frames and ranges may be varied or even be dynamic and variable, depending on the implementation.

As those skilled in the art will understand, a number of variations may be made in the disclosed embodiments, all without departing from the scope of the invention, which is defined solely by the appended claims. It should be noted that although the features and elements are described in particular combinations, each feature or element can be used alone without other features and elements or in various combinations with or without other features and elements. The methods or flow charts provided may be implemented in a computer program, software, or firmware tangibly embodied in a computer-readable storage medium for execution by a general-purpose computer or processor.

Examples of computer-readable storage mediums include a read only memory (ROM), random-access memory (RAM), a register, cache memory, semiconductor memory devices, magnetic media such as internal hard disks and removable disks, magneto-optical media, and optical media such as CD-ROM disks.

Suitable processors include, by way of example, a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, or any combination of thereof.

What is claimed is:

1. A method for dynamic risk assessment of a flight in a fleet of aircraft, the method comprising:
fetching state data for a flight from a distributed database configured to store state data for a plurality of flights being performed by the fleet of aircraft;
running a plurality of simulations, by a plurality of risk modules, based on the state data for the flight, each of the plurality of risk modules configured to assess a type of risk and output a risk score, the plurality of simulations resulting in a plurality of risk scores for the flight;
merging the plurality of risk scores for the flight by stacking the plurality of risk scores for the flight beginning with a highest risk score until a merged risk threshold is exceeded or each of the plurality of risk scores have been stacked;
providing merged risk score data to an automated system configured to generate an automated message to the flight in response to the merged risk score data.

2. The method of claim 1, further comprising presenting, by a user interface, a graphical representation of the merged risk score data for the flight, the graphical representation showing at least a merged risk score and the highest risk score, the merged risk score comprising an ordered stack of the plurality of risk scores.

3. The method of claim 1, further comprising causing the automated system to generate the automated message to the flight, wherein one or more of the plurality of risk modules exceeds an individual risk threshold.

4. The method of claim 2, further comprising causing the automated system to generate the automated message to the flight, wherein the merged risk score exceeds the merged risk threshold.

5. The method of claim 1, wherein the automated message is configured to cause an adjustment to a flight path.

6. The method of claim 1, wherein the state data comprises a population density being overflown.

7. The method of claim 1, wherein the state data comprises a weather forecast.

8. The method of claim 1, wherein the state data comprises observed weather.

9. The method of claim 1, wherein the state data comprises a time of day.

10. The method of claim 1, wherein the fleet comprises two or more homogeneous vehicles.

11. The method of claim 1, wherein the fleet comprises two or more heterogeneous vehicles.

12. The method of claim 1, wherein the fleet includes a wind-driven vehicle.

13. The method of claim 1, wherein the fleet includes an airship.

14. The method of claim 1, wherein the fleet includes a fixed-wing aircraft.

15. The method of claim 1, wherein the plurality of risk modules comprises at least one of a critical battery module, a thermal runaway module, a population density module, or a ACS usage module.

16. A distributed computing system comprising:
a distributed database configured to store state data for a plurality of flights being performed by a fleet of aircraft;
one or more processors configured to dynamically assess risk for the plurality of flights, the one or more processors configured to:
fetch state data for a flight from the distributed database;
implement a plurality of risk modules to run a plurality of simulations based on the state data for the flight, each of the plurality of risk modules configured to assess a type of risk and output a risk score, the plurality of simulations resulting in a plurality of risk scores for the flight;
merge the plurality of risk scores for the flight by stacking the plurality of risk scores for the flight beginning with a highest risk score until a maximum merged risk score is exceeded; and
provide merged risk score data to an automated system configured to generate an automated message to the flight in response to the merged risk score data.

17. The system of claim 16, further comprising a display configured to present a user interface configured to present a graphical representation of the merged risk score data for the flight, the graphical representation showing at least a merged risk score and the highest risk score, the merged risk score comprising an ordered stack of the plurality of risk scores.

18. A method for dynamic risk assessment of a fleet of aircraft, the method comprising:
fetching state data for a fleet of aircraft from a distributed database;
assessing a first type of risk for the fleet by running a first plurality of simulations, by a first risk module, based on the state data for the fleet of aircraft, the first plurality of simulations resulting in a first plurality of risk scores for the first type of risk for a plurality of flights in the fleet;
assessing a second type of risk for the fleet by running a second plurality of simulations, by a second risk module, based on the state data for the fleet of aircraft, the second plurality of simulations resulting in a second plurality of risk scores for the second type of risk for the plurality of flights in the fleet;
generating fleet risk assessment data comprising a merged fleet risk score comprising the first plurality of risk scores representing the first type of risk and the second plurality of risk scores representing the second type of risk; and
providing the fleet risk assessment data to an automated system configured to generate an automated message to one or more flights in the fleet in response to the fleet risk assessment data.

19. The method of claim 18, further comprising:
aggregating the first plurality of risk scores to generate a first aggregate risk score; and
aggregating the second plurality of risk scores to generate a second aggregate risk score,
wherein the merged fleet risk score merges the first aggregate risk score with the second aggregate risk score.

20. The method of claim 18, wherein the first type of risk is population overflown, the first aggregate risk score indicating whether a threshold cumulative population overflown by the fleet has been met or exceeded.
